(19) United States
(12) Patent Application Publication
(10) Pub. No.: US 2013/0302616 A1
(43) Pub. Date: Nov. 14, 2013

(54) METHOD FOR COATING A GRAPHITE MATERIAL WITH PYROLYTIC BORON NITRIDE AND A COATED ARTICLE OBTAINED BY THAT METHOD

(71) Applicant: SHIN-ETSU CHEMICAL CO., LTD., Tokyo (JP)

(72) Inventor: Shoji KANO, Annaka-shi (JP)

(21) Appl. No.: 13/889,403

(22) Filed: May 8, 2013

(30) Foreign Application Priority Data
May 10, 2012 (JP) 2012-108391

(51) Int. Cl. C23C 16/34

(52) U.S. Cl. CPC C23C 16/342
USPC 428/408; 427/255.4

(57) ABSTRACT

A method for coating a graphite body with pyrolytic boron nitride comprising steps of (1) densifying the surface of the graphite body by CVI treatment, (2) then treating the surface with a reactive gas, (3) and after that, forming a PBN coating film over the said treated surface; and also a coated article shown by FIG. 1 which is obtained by this method.

### TECHNICAL FIELD

The present invention relates to a method for coating pyrolytic boron nitride over a graphite body, and also to a thus obtained coated article; in particular the present invention relates to a method for coating pyrolytic boron nitride over a graphite body which is comprised of densifying the surface of the graphite body by CVI (Chemical Vapor Infiltration) treatment, then treating the surface with a reactive gas, and after that, forming a pyrolytic boron nitride coat over the said treated surface, and the invention also relates to a coated article obtained thereby.

### BACKGROUND TECHNOLOGY

A graphite article coated with pyrolytic boron nitride (also referred to as “PBN” in the present invention) is excellent in heat resistance, thermal shock resistance, chemical resistance, radiation resistance and thermal conductivity or the like, and as it has electric insulating characteristic, which is absent in a graphite-only article, it is quite useful as a material to make devices used in a system where carbon is not permitted.

PBN itself is synthetized by a chemical vapor deposition method Therefore, if an article is manufactured by using PBN itself, the configuration of the article is seriously limited. In contrast to this, in cases where an article is manufactured by depositing PBN on a graphite body, the configuration of an article of PBA-coated graphite is not limited since it is possible, at first, to form a raw graphite body into any desired configuration and then to deposit PBN upon the obtained configuration of graphite body. Furthermore it does not take time to perform PBA-coating over a graphite body. Therefore, it is possible to obtain with ease an article such as a device which has a complicated configuration having the characteristics of the PBN.

In fact, the field of its application is wide, and it can be used to make many things including, for example, a tray for wafer, a crucible for melting a raw material for vapor deposition, a heater, a reaction vessel, a heat shield device, and a crucible for crystal pulling.

One common method known for coating PBN over a graphite body is to expose the graphite body to reactive gases of BCl₃ and NH₃ under the conditions of a high temperature range from 1700° C. to 2300° C. and a reduced pressure of 1000 Pa or lower to obtain a vapor deposition of the PBN film.

However, the thermal expansion coefficient of the PBN coating film obtained in this method is different from that of the graphite. Therefore, this method had a problem in that the PBN deposit film is liable to come off.

Actually, there is a substantial difference between the thermal expansion coefficient of a commercially available general isotropic graphite, which is about 4 to 6×10⁻⁶ (/° C.), and the a-axis-direction thermal expansion coefficient of PBN, which is 1 to 3×10⁻⁶ (/° C.). On account of this, when the temperature falls to room temperature from the vapor deposition temperature, there occurs a displacement of 0.2 to 1% in dimension, and the PBN deposit film is liable to come off. Especially when the film thickness of the vapor-deposited film of PBN is 0.1 mm or greater, the detachment of the film increases considerably.

An approach was made in view of solving this problem in which the surface of a graphite body was treated with plasma and/or a reactive gas and after that the PBN film was formed over the thus treated surface by a chemical vapor deposition method, and a certain degree of improvement was reported (Japanese Unexamined Patent Publication Tokkai sho 62-207786). However, even in this approach, when a cycle of temperature raising and lowering was repeated rapidly, it was confirmed that the PBN coating film came off.

In particular, since the detachment of the PBN coating film occurs more frequently in the vicinities of corner areas where the stress of the film is concentrated, it was necessary to round off smoothly the corners of the graphite body without fail.

The present inventors studied extensively in order to solve the above problems, in particular, in order that a PBN coating film can be made to form over the surface of a graphite body, which makes it strong in thermal shock resistance, physically strong and thus hard to come off. As a result, they found that the problems can be solved when the surface of the graphite body is subjected to a CVI treatment to thereby densify it, and then the surface is treated with a reactive gas, and after that a PBN coating film is formed over the said surface, and thus the invention was completed.

### SUMMARY OF THE INVENTION

### The Problems to be Solved by the Invention

Therefore, it is the first object of the present invention to provide a method for coating a PBN film over the surface of a graphite body, wherein the PBN coating film, which is strong in thermal shock resistance, strong physically and also hard to come off, can be formed.

It is the second object of the present invention to provide a coated article comprised of a graphite body of which surface is coated with a PBN coating film which is strong in thermal shock resistance, strong physically and also hard to come off.

### Means to Solve the Problems

Namely, the present invention is a method for coating a graphite body with PBN characterized by comprising steps of densifying the surface of the graphite body by CVI treatment, then treating the surface with a reactive gas and after that forming a PBN coating film over the said treated surface, and a coated article obtained by this method.

It is preferable to use an oxidizing gas, a gaseous halide or ammonia as the above reactive gas (Claim 2), and it is particularly preferable to use a gaseous halide (Claim 3). In addition, it is preferable for the reason of cost reduction to carry out consecutively the CVI treatment, the surface treatment with a reactive gas and the forming of the PBN coating layer in a single reactor (Claim 4).

### Effects of the Invention

In accordance with the method of the present invention, it is possible to form over the surface of a graphite body a PBN coating film which is strong in thermal shock resistance, strong physically and thus hard to come off, and by virtue of this, it is now possible to obtain a coated article having the characteristics of both graphite body and PBN. In addition, by carrying out consecutively the process of the CVI treatment, the surface treatment with a reactive gas and the deposition of the PBN coating layer in a single reactor, it becomes possible to supply a coated article made of a graphite body coated with a PBN film at a low price.

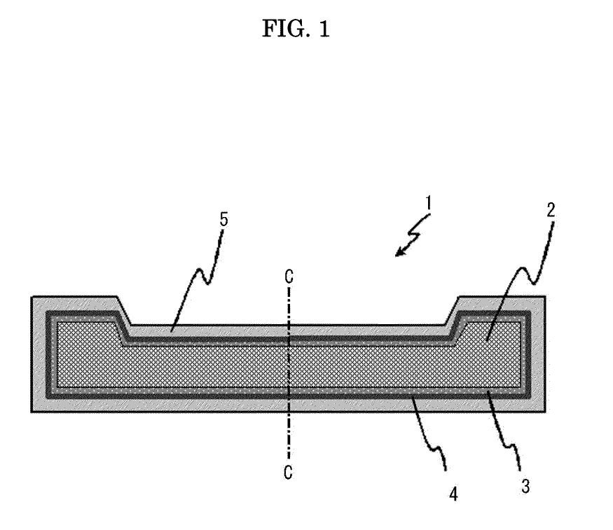

### BRIEF DESCRIPTION OF DRAWINGS

[FIG. 1] A conceptual cross sectional view of a tray for wafer, manufactured by the method of the present invention.

### EMBODIMENT FOR CARRYING OUT THE INVENTION

Hereafter, the present invention will be described in more detail, but the invention should not be construed as being limited to such description.

The method for coating a graphite body according to the present invention includes steps of densifying the surface of the graphite body by CVI treatment, then treating the surface with a reactive gas and after that, forming a PBN coating film over the said treated surface. By means of this method, it is possible to form over the surface of the graphite body a PBN film which is strong in thermal shock resistance, strong physically and thus hard to come off.

Here, the CVI (Chemical Vapor Infiltration) treatment is defined as a publicly known method designed to densify the surface of base material by filling voids of the base material with deposition of vapor phase pyrolytic carbon.

In the present invention, it is preferable that the temperature is within the range from 800 to 1400° C. and the pressure is between 10 and 5000 Pa, as the reaction condition for the CVI treatment. Examples of a pyrolytic gas used may be an aliphatic saturated hydrocarbon such as methane, ethane and propane, or an aromatic hydrocarbon such as benzene.

In the present invention, by applying the CVI treatment to the surface of the graphite body, it is possible to densify the surface layer of the graphite body so that damaged parts caused by machining and grinding can be repaired and strengthened. As a result, the detachment of graphite particles from the surface of the graphite body can be prevented. If the damaged parts are left inside the surface layer of the graphite body, the coated PBN film is liable to come off from such surface layer part of the graphite body. Therefore, it is preferable that the pyrolytic carbon is deposited to fill to an area deeper than where the damaged parts caused by machining and grinding exist.

The material for the graphite body used in the present invention is not limited in particular, and it is possible to use a molded heat insulating material having a bulk density from 0.1 to 0.3 g/cm³. However, it is preferable to use a compact extruded material, molded material, or CIP (Cold Isostatic Press) material having a bulk density from 1.5 to 2.1 g/cm³.

In the present invention, it is preferable that the graphite material is first shaped into a desired configuration before coating the PBN over the surface of the graphite material. Specific examples of such configurations can be those of a tray for wafer, a crucible for melting a raw material for vapor deposition, a heater, a reaction vessel, a heat shield device, and a crucible for crystal pulling. In the present invention, it is possible that various graphite parts are assembled to a graphite body as a whole, then a series of pre-treatments are carried out on the surface of the graphite body and after that, the PBN film is formed on the surface. And also, in the present invention, it is possible that a series of pre-treatments are carried out on various graphite parts respectively, then the various graphite parts are assembled to a graphite body as a whole and after that, the PBN film is formed on the surface.

In the method of the present invention, the surface of the graphite body already treated by the above CVI method is further treated with a reactive gas. Examples of such reactive gas include oxidizing gases such as air, water vapor, carbon dioxide and a nitrogen oxide, gaseous halides such as BCl₃, AlCl₃ and HCl, and ammonia.

The surface treatment using the above-mentioned reactive gases is carried out by exposing the densified graphite surface to a reactive gas under the condition of a temperature range from 500 to 2400° C. As a result of this treatment, the densified surface of the graphite body is activated. In particular, it is preferable to carry out the surface treatment using the gaseous halide, since the gaseous halide reacts with the densified surface of the graphite body to activate the graphite surface, and as a result, the adhesive properties between the graphite body and the PBN coating film is improved.

After the above-described surface treatments by means of CVI and the reactive gas are carried out, BCl₃ and NH₃ are introduced to react with each other in a conventional manner at 1700 to 2300° C. under a pressure of 1000 Pa or lower to thereby cause a chemical vapor deposition of PBN on the treated surface of the graphite body. The PBN vapor deposition film obtained in this manner has strong adhesive properties to the surface of the graphite body, irrespective of the thermal expansion coefficient, the grain size, the surface quality in shape, etc. of the graphite body so that the PBN film is hardly liable to come off.

FIG. 1 is a conceptual cross sectional drawing of a PBN-coated tray for wafer manufactured by the method according to the present invention. As is seen, an inventive coated article as obtained by the method of the present invention has three layers over its graphite core body, namely, a graphite layer condensed by the CVI treatment, a layer treated by a reactive gas, and a PBN coating layer.

The coating thickness of the PBN coating layer is preferably 0.01 to 0.5 mm, but 0.1 to 0.3 mm is more preferable. When the PBN coating layer is too thick, even though the PBN coating layer would not come off from the surface of the graphite body, there is a tendency for a separation to occur between PBN sub-layers within the PBN coating layer. Because of that, it is preferable that the layer does not exceed 0.5 mm in thickness. In addition, when the PBN coating layer is too thin, the quality of the PBN is not sufficient. Because of that, it is necessary that the thickness of the layer is 0.01 mm or greater.

In the present invention, it is also possible to carry out consecutively the processes of the CVI treatment, the surface treatment by a reaction gas and PBN coating layer deposition in a single reactor. By adopting this consecutive operation in a single reactor, it is possible to reduce the manufacturing cost.

The present invention will now be described in more detail by means of Example and Comparative examples, but the present invention should not be construed to be limited by these Example and Comparative examples.

### EXAMPLE

An isotropic graphite body ground by a machine to a dimension of 100 mm×100 mm×10 mm (thermal expansion coefficient: 5×10⁻⁶/° C.; bulk density:1.7 g/cm³) was put in a high temperature vapor deposition furnace, and the furnace was evacuated with a vacuum pump. While maintaining the vacuum state, the temperature was raised to 1000° C. by heating, and after that, methane gas was supplied at a flow rate of 1 litter per minute, then the pressure inside the furnace was being controlled to 20 Pa and thus the surface of graphite was treated by CVI for 15 minutes. After that, the high temperature vapor deposition furnace was further heated to about 1400° C. When the temperature reached 1400° C., BCl₃ as the reactive gas was supplied at a flow rate of 1 litter per minute, and thereby the surface treatment with the reaction gas was carried out for 15 minutes. The high temperature vapor deposition furnace was further heated to about 2000° C., and while maintaining the reaction pressure at 1000 Pa or lower at the high temperature of 2000° C., ammonia gas was also supplied, then a reaction between BCl₃ and NH₃ was carried out in order to form a PBN coating film having 0.3 mm thickness (thermal expansion coefficient: 3×10⁻⁶/° C.).

The inside of the vapor deposition furnace was cooled to room temperature and the treated isotropic graphite body was retrieved, and it was found that the PBN coating film was strongly adhered and none of it came off.

The PBN-coated article obtained in this manner was heated by a lamp in an evaluation-purpose vacuum furnace to 1000° C. at a high rate, and after that, the heating was stopped and the temperature was lowered to 200° C., next, the heating by a lump was restarted to raise the temperature to 1000° C. within about one minute, and this rapid heating and cooling cycle was repeated in order to observe the detachment of the film.

The PBN coated article of the present invention did not show any detachment of the coating layer even after 100 times of the rapid heating and cooling cycle. Also, through an observation by an electron microscope and a chemical analysis conducted with respect to the vicinities of the interface cut into a cross-section, it was confirmed that the graphite core body was densified in the vicinities of the interface, and that boron carbide was formed in the boundary. It is assumed that the layer containing the formed boron carbide was a layer formed as a result of the treatment of the surface with the reactive gas, BCl₃.

### Comparative Example 1

A graphite body was prepared in the same manner as in Example 1, but no CVI treatment was conducted upon the surface of this graphite body; then upon this graphite body a surface treatment with the reaction gas was carried out under the same conditions as in Example 1, whereby a PBN coating film was formed, and when the graphite body was retrieved after the inside of the vapor deposition furnace was cooled to the room temperature, it was observed that the PBN coating film was strongly adhered to it and no detachment occurred. This PBN coated article was subjected to the same rapid heating and cooling cycle in the vacuum furnace in the same manner as in Example 1 for evaluation, and it was observed that a film detachment occurred at a corner area when the cycle was repeated for 30 times.

### Comparative Example 2

A graphite body was prepared in the same manner as in Example 1, but no CVI treatment and no surface treatment with a reactive gas were carried out on the surface of this graphite body; then upon this graphite body a PBN coating film was formed under the same conditions as in Example 1. When the graphite body was retrieved after the inside of the vapor deposition furnace was cooled to room temperature, it was observed that there were already detachments of the PBN coating film.

It is confirmed from the above-described Example and Comparative examples that a good PBN coating was obtained as a result of the present invention.

The entire disclosures of all applications, patents and publications, cited herein and of corresponding application No. 2012-108391 JP, filed May 10, 2012, are incorporated by reference herein.

### INDUSTRIAL APPLICABILITY

In accordance with the method of the present invention, it is possible to form over the surface of a graphite body a PBN coating film, which is strong in thermal shock resistance, strong physically and thus hard to come off, and by virtue of this, it is now possible to obtain a coated article having the characteristics of both graphite body and PBN. In particular, since the PBN coated article according to the present invention is significantly improved in that the tendency of the PBN coating film to come off in the vicinities of the corner areas, where the stress of the film is concentrated, is substantially reduced, and it is now not absolutely necessary to round off smoothly all the corners of the graphite body, and therefore a lot of labor and time can be saved. In addition, by carrying out consecutively the processes of the CVI treatment, the surface treatment with the reactive gas, and the deposition of the PBN coating layer in a single reactor, it is possible to supply a coated article made of a graphite body coated with a PBN film at a low price.

### EXPLANATIONS OF LETTERS OR NUMERALS

1: Conceptual cross sectional view of a tray for wafers, which is the coated article of the present invention.
2: Graphite body
3: Graphite layer condensed by CVI treatment
4: Layer treated with a reactive gas
5: PBN coating film

1. A method for coating a graphite body with pyrolytic boron nitride comprising the processes comprised of densifying a surface of the graphite body by a CVI treatment, then treating the surface with a reactive gas, and after that forming a PBN coating film over the said treated surface.

2. The method for coating a graphite body with pyrolytic boron nitride as claimed in claim 1, wherein any one kind of reactive gases selected from an oxidizing gas, a gaseous halide and ammonia is used as the said reactive gas.

3. The method for coating a graphite body with pyrolytic boron nitride as in claim 2, wherein the said reactive gas is a gaseous halide.

4. The method for coating a graphite body with pyrolytic boron nitride as claimed in claim 1, wherein the said CVI treatment, the said surface treatment with the reactive gas and the said forming of the pyrolytic boron nitride coating layer are carried out consecutively in a single reactor.

5. A coated article having layers on a surface of a graphite body, the layers are comprised of, in order, a graphite layer densified by the CVI treatment, a treated layer with the reactive gas, and pyrolytic boron nitride coating layer.
